(19) United States
(12) Patent Application Publication
(10) Pub. No.: US 2026/0202254 A1
(43) Pub. Date: Jul. 16, 2026

(54) ELECTRONIC DEVICE AND METHOD FOR DETECTING TEMPERATURE THEREOF

(71) Applicant: ASUSTeK COMPUTER INC., Taipei City (TW)

(72) Inventors: Chih-Yao Kuo, Taipei City (TW); Ya-Han Chang, Taipei City (TW); Huang-Chieh Huang, Taipei City (TW)

(73) Assignee: ASUSTeK COMPUTER INC., Taipei City (TW)

(21) Appl. No.: 19/366,534

(22) Filed: Oct. 23, 2025

(30) Foreign Application Priority Data
Jan. 10, 2025 (TW) 114101004

(51) Int. Cl. G01K 1/02; G01R 21/133

(52) U.S. Cl. CPC G01K 1/026; G01R 21/133

(57) ABSTRACT

The disclosure provides an electronic device and a method for detecting temperature thereof. The method for detecting temperature is adapted to the electronic device including a plurality of temperature sensors and includes the following steps. An operating status of the electronic device is determined. A plurality of selected temperature sensors are selected from the plurality of temperature sensors according to the operating status of the electronic device. A plurality of reference temperatures sensed by the plurality of selected temperature sensors are obtained. A surface temperature of the electronic device is determined according to the plurality of reference temperatures.

### CROSS-REFERENCE TO RELATED APPLICATION

This application claims the priority benefit of Taiwan application serial no. 114101004, filed on Jan. 10, 2025. The entirety of the above-mentioned patent application is hereby incorporated by reference herein and made a part of this specification.

### BACKGROUND OF THE INVENTION

### Field of the Invention

The disclosure relates to an electronic device and a method for detecting temperature thereof.

### Description of Related Art

With the advancement of technology, consumer electronic devices have become part of modern people's daily lives. The electronic elements inside consumer electronic devices consume electrical energy during operation, and part of this electrical energy is converted into heat energy. Heat is generated particularly when the processor, the graphics processing unit (GPU), or other high-power elements are in operation. Therefore, these consumer electronic devices generate heat during use, causing the temperature of the device surface to be increased. It is known that when the skin of the user touches the high-temperature surface of the device, there is discomfort, and even low-temperature burns may be caused due to long-term contact. Therefore, it is necessary to monitor the surface temperature of electronic devices in real time. Currently, most of the surface temperatures of electronic devices are estimated by using the temperature sensed by a single temperature sensor and a fixed calculation method. However, this temperature estimation method is not accurate.

### SUMMARY OF THE INVENTION

The disclosure provides a method for detecting temperature adapted to an electronic device including a plurality of temperature sensors and includes the following steps. An operating status of the electronic device is determined. A plurality of selected temperature sensors are selected from the plurality of temperature sensors according to the operating status of the electronic device. A plurality of reference temperatures sensed by the plurality of selected temperature sensors are obtained. A surface temperature of the electronic device is determined according to the plurality of reference temperatures.

The disclosure further provides an electronic device including a plurality of temperature sensors and a processor. The processor is coupled to the plurality of temperature sensors and configured to execute the following steps. An operating status of the electronic device is determined. A plurality of selected temperature sensors are selected from the plurality of temperature sensors according to the operating status of the electronic device. A plurality of reference temperatures sensed by the plurality of selected temperature sensors are obtained. A surface temperature of the electronic device is determined according to the plurality of reference temperatures.

Based on the above, in an embodiment of the invention, some selected temperature sensors may be selected from the plurality of temperature sensors disposed at different locations according to the operating status of the electronic device. Furthermore, the surface temperature of the electronic device may be accurately estimated according to the reference temperatures sensed by the selected temperature sensors. Accordingly, the estimation of the surface temperature may be more accurate, which is beneficial to maintaining the performance stability of the device and the safety of the user.

### BRIEF DESCRIPTION OF THE DRAWINGS

FIG. 1 is a block diagram of an electronic device shown according to an embodiment of the invention.

FIG. 2 is a schematic diagram of a plurality of temperature sensors shown according to an embodiment of the invention.

FIG. 3 is a flowchart of a method for detecting temperature shown according to an embodiment of the invention.

FIG. 4 is a schematic diagram of a plurality of reference temperatures and surface temperatures shown according to an embodiment of the invention.

FIG. 5 is a flowchart of a method for detecting temperature shown according to an embodiment of the invention.

FIG. 6 is a flowchart of a method for detecting temperature shown according to an embodiment of the invention.

### DESCRIPTION OF THE EMBODIMENTS

A portion of the embodiments of the disclosure is described in detail hereinafter with reference to figures. In the following, the same reference numerals in different figures should be considered to represent the same or similar elements. These embodiments are only a portion of the invention and do not disclose all possible implementations of the invention. Rather, the embodiments are merely examples of devices and methods within the scope of the invention.

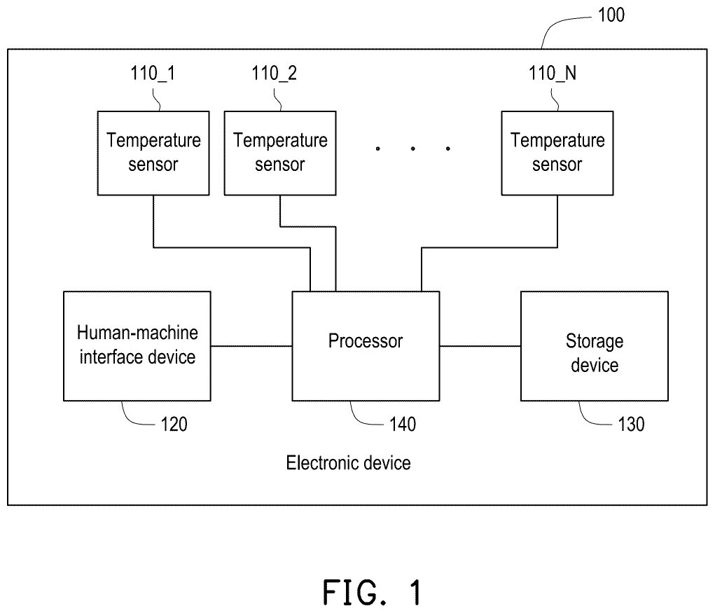

FIG. 1 is a schematic diagram of an electronic device shown according to an embodiment of the invention. In some embodiments, an electronic device 100 is a mobile phone, a game console, a tablet computer, a notebook computer, a smart wearable device, a server device, or a projector, etc., and the disclosure is not limited thereto. The electronic device 100 may include a plurality of temperature sensors 110_1 to 110_N, a human-machine interface device 120, a storage device 130, and a processor 140.

The plurality of temperature sensors 110_1 to 110_N are disposed inside the electronic device 100 to sense temperature. The disclosure does not limit the number of the plurality of temperature sensors 110_1 to 110_N, which is determined according to actual applications. The temperature sensors 110_1 to 110_N may include a plurality of thermal sensitive elements disposed on at least one circuit board. In some embodiments, the thermal sensitive elements are thermistors, thermocouples, or other thermal sensitive elements for sensing temperature, and the disclosure is not limited thereto. In an embodiment, the temperature sensors 110_1 to 110_N are distributed in different areas in the electronic device 100. In different embodiments, the temperature sensors 110_1 to 110_N are disposed on a plurality of circuit boards. In different embodiments, the temperature sensors 110_1 to 110_N are disposed on different surfaces of the same circuit board.

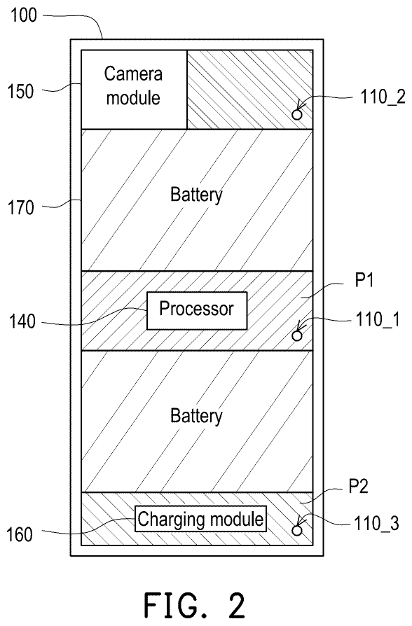

FIG. 2 is a schematic diagram of a plurality of temperature sensors shown according to an embodiment of the invention. The electronic device 100 is taken as an example to include three temperature sensors 110_1 to 110_3. In an embodiment, the temperature sensor 110_1 is disposed on a main circuit board P1 of the electronic device 100 and at a location located closer to the processor 140. From another perspective, the temperature sensor 110_1 is disposed in a hot area in the electronic device 100. Specifically, the hot area in the electronic device 100 is the area near the processor 140 since the processor 140 performing complex computing tasks is the main heat source of the electronic device 100.

Moreover, the temperature sensor 110_2 and the temperature sensor 110_3 is disposed at locations in the electronic device 100 far away from the processor 140. In FIG. 2, the temperature sensor 110_2 is disposed at the top of the electronic device 100, and the temperature sensor 110_3 is disposed at the bottom of the electronic device 100. From another perspective, since the temperature sensor 110_2 and the temperature sensor 110_3 are far away from the main heat source of the electronic device 100 (i.e., the processor 140), the temperature sensor 110_2 and the temperature sensor 110_3 are located in a cold area in the electronic device 100.

In an embodiment, the electronic device 100 is a mobile phone, and the temperature sensor 110_2 is disposed at a location near a camera module 150. The camera module 150 may include an image sensor and a lens. In an embodiment, the temperature sensor 110_3 is disposed at a location near a charging module 160 including a charging circuit and a charging port, and is also disposed on a circuit board P2 different from the main circuit board P1. In this case, the sensed temperatures of the temperature sensor 110_2 and the temperature sensor 110_3 are less affected by the processor 140. It should be noted that the temperature sensed by the temperature sensor 110_2 is significantly related to whether the camera module 150 is in operation, and the temperature sensed by the temperature sensor 110_3 is significantly related to whether the electronic device 100 is being charged.

In the embodiment, the plurality of temperature sensors 110_1 to 110_N may include a primary temperature sensor disposed in a hot area in the electronic device 100 and a secondary temperature sensor disposed in a cold area in the electronic device 100. Taking FIG. 2 as an example, the temperature sensor 110_1 is a primary temperature sensor located in a hot area, and the temperature sensor 110_2 and the temperature sensor 110_3 are secondary temperature sensors located in a cold area.

The human-machine interface device 120 may include one or a plurality of output devices, such as a display, a speaker, or a prompt light, etc. The user of the electronic device 100 may interact with the electronic device 100 via the human-machine interface device 120. In some embodiments, the processor 140 may provide a temperature prompt related to the surface temperature to the user via an output device of the human-machine interface device 120.

In an embodiment, the storage device 130 is used to store data and a software module, etc., and may be, for example, any type of fixed or removable random-access memory (RAM), read-only memory (ROM), flash memory, or other similar devices, integrated circuits, and a combination thereof.

The processor 140 is coupled to the temperature sensors 110_1 to 110_N, the human-machine interface device 120, and the storage device 130. In an embodiment, the processor 140 is a general-purpose processor, a special-purpose processor, a conventional processor, a digital signal processor, a microprocessor, one or a plurality of microprocessors combined with a digital signal processor core, a controller, a microcontroller, an application-specific integrated circuit (ASIC), a field-programmable gate array (FPGA), any other type of integrated circuit, a state machine, or other similar devices.

In an embodiment, the processor 140 accesses and executes the software module recorded in the storage device 130 to implement the method for detecting temperature in an embodiment of the invention. In an embodiment, the software module is broadly interpreted to mean command, command set, code, program code, program, software package, thread, procedure, function, etc., regardless of whether the software module is called software, firmware, middleware, microcode, hardware description language, or something else.

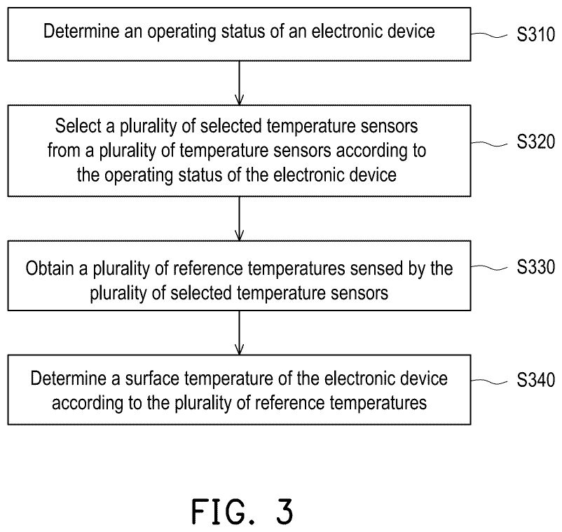

FIG. 3 is a flowchart of a method for detecting temperature shown according to an embodiment of the invention. Please refer to FIG. 1 and FIG. 3. The method of the present embodiment is applicable to the electronic device 100 in an above embodiment. The following describes the detailed steps of the method for detecting temperature of the present embodiment in conjunction with various elements in the electronic device 100.

In step S310, the processor 140 determines the operating status of the electronic device 100. In step S320, the processor 140 selects a plurality of selected temperature sensors from the plurality of temperature sensors 110_1 to 110_N according to the operating status of the electronic device 100. In an embodiment, the selected temperature sensors are some or all of the plurality of temperature sensors 110_1 to 110_N. Specifically, according to the operating status of the electronic device 100, the processor 140 may select a selected temperature sensor adapted to participate in the estimation of the surface temperature from the plurality of temperature sensors 110_1 to 110_N.

In some embodiments, the operating status of the electronic device 100 may include a hardware operating status of the electronic device 100.

In some embodiments, the operating status of the electronic device 100 includes whether the heat source element near the temperature sensor is in operation, that is, whether the heat source element is executing a specific function. The heat source element may include the processor 140, the camera module 150, the charging module 160, a wireless communication chip, a battery 170, or other electronic elements generating heat of the electronic device 100. For example, the operating status of the electronic device 100 may include whether the camera module 150 is executing a camera function. The operating status of the electronic device 100 may include whether the charging module 160 is executing a charging function. The operating status of the electronic device 100 may include whether the wireless communication chip is executing a data transceiving function.

In some embodiments, the operating status of the electronic device 100 includes the operating status of the heat source element near the temperature sensor. For example, the operating status of the electronic device 100 may include the charging current of the charging module 160. Alternatively, the operating status of the electronic device 100 may include an activation duration of the camera module 150. Alternatively, the operating status of the electronic device 100 may include a load status of the processor 140.

In some embodiments, the operating status of the electronic device 100 may include a software operating status of the electronic device 100. In some embodiments, the operating status of the electronic device 100 may include the type of application being executed by the electronic device 100. For example, the processor 140 may determine whether to select a temperature sensor located near the camera module according to whether the camera application is being executed.

In step S330, the processor 140 obtains a plurality of reference temperatures sensed by a plurality of selected temperature sensors. In step S340, the processor 140 determines the surface temperature of the electronic device 100 according to the plurality of reference temperatures. That is, after selecting the plurality of selected temperature sensors according to the hardware operating status and/or the software operating status of the electronic device 100, the processor 140 may estimate the surface temperature of the electronic device 100 according to the reference temperatures respectively measured by the selected temperature sensors. In other words, in response to different operating statuses of the electronic device 100, the processor 140 may adopt the reference temperatures of different combinations of the plurality of temperature sensors to determine the surface temperature of the electronic device 100, rather than determining the surface temperature via a fixed calculation method. As mentioned above, since temperature sensors not adapted to estimate the surface temperature are eliminated, the estimation accuracy of the surface temperature may be effectively improved.

In some embodiments, the processor 140 may execute a function based on the surface temperature of the electronic device 100. More specifically, in some embodiments, the processor 140 may control the display in the human-machine interface device 120 to display the surface temperature of the electronic device 100, so that the user may understand the surface temperature of the electronic device 100. Alternatively, in some embodiments, the processor 140 may provide a warning via the human-machine interface device 120 according to the surface temperature of the electronic device 100 to prevent the user from being burned by low temperature. Alternatively, in some embodiments, the processor 140 may perform a thermal protection operation according to the surface temperature of the electronic device 100 to prevent the electronic device 100 from hardware damage due to over-high temperature and ensure safety in use.

In some embodiments, the processor 140 may estimate the surface temperature of the electronic device 100 according to the reference temperatures via function calculation or table lookup. In some embodiments, the processor 140 may estimate the surface temperature of the electronic device 100 by performing a weighted sum operation on the reference temperatures.

In some embodiments, the plurality of temperature sensors 110_1 to 110_N include a primary temperature sensor and at least one secondary temperature sensor. The primary temperature sensor is disposed in a hot area in the electronic device 100, and the at least one secondary temperature sensor is disposed in at least one cold area in the electronic device 100. The selected temperature sensors include at least one of the primary temperature sensor and the at least one secondary temperature sensor. That is, the processor 140 may determine the surface temperature of the electronic device 100 according to the reference temperatures sensed by the primary temperature sensor in the hot area and the reference temperatures sensed by the at least one secondary temperature sensor in the cold area. By simultaneously considering the sensed temperatures in the hot area and the cold area, the accuracy of estimating the surface temperature of the electronic device 100 may be effectively improved.

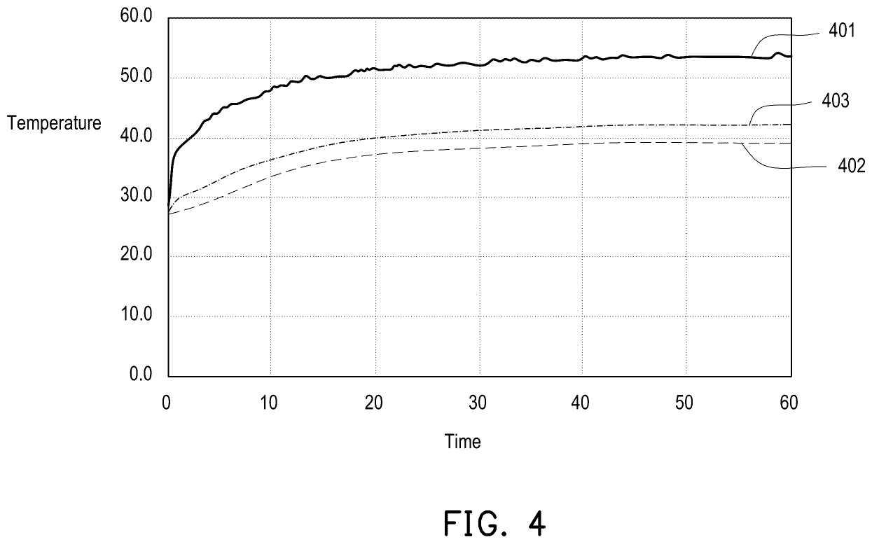

FIG. 4 is a schematic diagram of a plurality of reference temperatures and surface temperatures shown according to an embodiment of the invention. The reference temperature sensed by the primary temperature sensor located in the hot area are shown as a temperature rise curve 401. The reference temperature sensed by the secondary temperature sensor located in the cold area is shown as a temperature rise curve 402. By performing a weighted sum operation on the reference temperature sensed by the primary temperature sensor and the reference temperature sensed by the secondary temperature sensor, the processor 140 may estimate the surface temperature of the electronic device 100 as shown in a temperature rise curve 403. The sum of the plurality of weighting coefficients used in the weighted sum operation is 1, but the actual values of these weighting coefficients may be determined via experiments and tests, and the disclosure is not limited thereto.

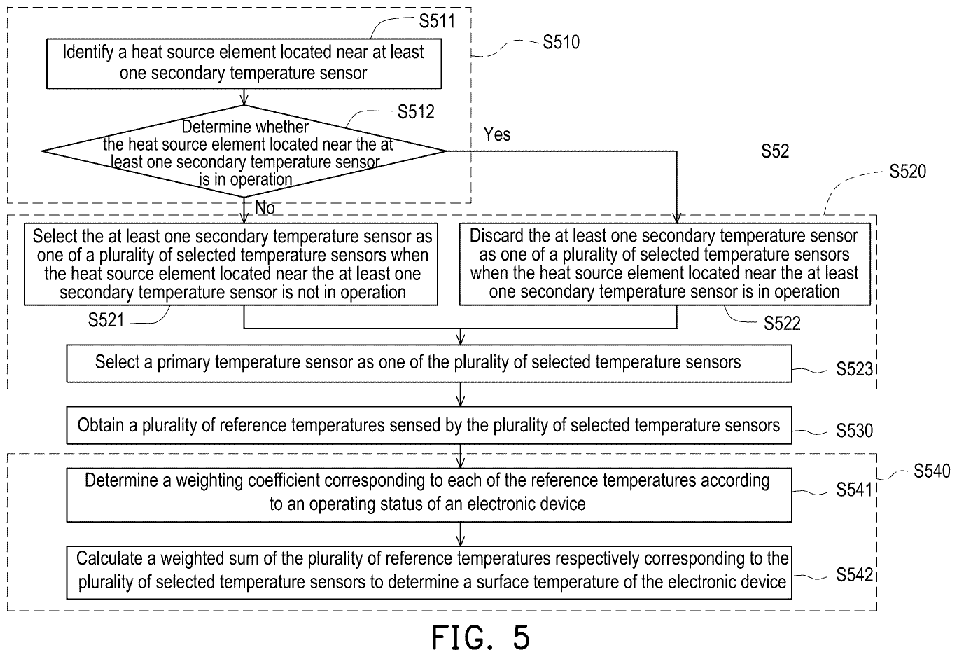

FIG. 5 is a flowchart of a method for detecting temperature shown according to an embodiment of the invention. Please refer to FIG. 1 and FIG. 5. The method of the present embodiment is applicable to the electronic device 100 in an above embodiment. The following describes the detailed steps of the method for detecting temperature of the present embodiment in conjunction with various elements in the electronic device 100.

In step S510, the processor 140 determines the operating status of the electronic device 100. In the present embodiment, step S510 may be implemented as step S511 to step S512.

In the present embodiment, the plurality of temperature sensors 110_1 to 110_N include a primary temperature sensor and at least one secondary temperature sensor. The primary temperature sensor is disposed in a hot area in the electronic device 100, and the at least one secondary temperature sensor is disposed in at least one cold area in the electronic device 100.

In step S511, the processor 140 identifies a heat source element located near the at least one secondary temperature sensor. In step S512, the processor 140 determines whether the heat source element located near the at least one secondary temperature sensor is in operation. Specifically, although the secondary temperature sensor is located in a cold area in the electronic device 100, the heat source element near the secondary temperature sensor may affect the reference temperature sensed by the secondary temperature sensor. Therefore, the processor 140 determines whether the secondary temperature sensor participates in the estimation of the surface temperature according to whether the heat source element near the secondary temperature sensor is in operation.

In step S520, the processor 140 selects a plurality of selected temperature sensors from the plurality of temperature sensors 110_1 to 110_N according to the operating status of the electronic device 100. In the present embodiment, step S520 may be implemented as step S521 to step S523.

In step S521, when the heat source element located near the at least one secondary temperature sensor is not in operation (determined as no in step S512), the processor 140 selects the at least one secondary temperature sensor as one of the plurality of selected temperature sensors. In step S522, when the heat source element located near the at least one secondary temperature sensor is in operation (determined as yes in step S512), the processor 140 discards the at least one secondary temperature sensor as one of the plurality of selected temperature sensors.

That is, when the reference temperature sensed by a certain secondary temperature sensor is increased due to the heat generated by a nearby heat source element, the processor 140 may not select the secondary temperature sensor to participate in the estimation of the surface temperature. On the contrary, when the reference temperature sensed by a certain secondary temperature sensor is not increased by the nearby heat source element, the processor 140 may select the secondary temperature sensor to participate in the estimation of the surface temperature.

Taking FIG. 2 as an example, the reference temperature sensed by the temperature sensor 110_2 as the secondary temperature sensor is significantly affected by whether the nearby camera module 150 is in operation. When the camera module 150 is in operation, the reference temperature sensed by the temperature sensor 110_2 is significantly increased due to the heat generated by the camera module 150. Therefore, when the camera module 150 is in operation, the processor 140 may not select the temperature sensor 110_2 and may not determine the surface temperature according to the reference temperature of the temperature sensor 110_2. Alternatively, the reference temperature sensed by the temperature sensor 110_3 as the secondary temperature sensor may be significantly affected by whether the nearby charging module 160 is being charged. When the charging module 160 is charging, the reference temperature sensed by the temperature sensor 110_3 is significantly increased due to the heat generated by the charging module 160. Therefore, when the charging module 160 is charging, the processor 140 may not select the temperature sensor 110_3 and may not determine the surface temperature according to the reference temperature of the temperature sensor 110_3.

In step S523, the processor 140 selects the primary temperature sensor as one of the plurality of selected temperature sensors. As described above, the processor 140 may select one or a plurality of primary temperature sensors in a hot area to participate in the estimation of the surface temperature. Taking FIG. 2 as an example, the processor 140 may select the temperature sensor 110_1 disposed on the main circuit board P1 and located near the processor 140 as the primary temperature sensor.

In step S530, the processor 140 obtains a plurality of reference temperatures sensed by the plurality of selected temperature sensors. In step S540, the processor 140 determines the surface temperature of the electronic device 100 according to the plurality of reference temperatures. In the present embodiment, step S540 may be implemented as step S541 to step S542.

In step S541, the processor 140 determines a weighting coefficient corresponding to each reference temperature according to the operating status of the electronic device 100. In step S542, the processor 140 calculates a weighted sum of the plurality of reference temperatures respectively corresponding to the plurality of selected temperature sensors to determine the surface temperature of the electronic device 100.

Specifically, after determining whether each of the temperature sensors 110_1 to 110_N participates in the estimation of the surface temperature, the processor 140 may obtain the plurality of selected temperature sensors. It is known that the selected temperature sensors may be changed according to the change in the operating status of the electronic device 100. In this case, the processor 140 may determine the surface temperature of the electronic device 100 according to different weighted sum calculation equations. Different weighted sum calculation equations have different numbers of weighted items and weighting coefficients.

In some embodiments, the processor 140 may determine the weighting coefficient corresponding to each selected temperature sensor by looking up a table. In some embodiments, the weighting coefficient corresponding to each selected temperature sensor may be a fixed preset value.

Taking FIG. 2 as an example, when the camera module 150 is not in operation and the charging module 160 is being charged, the processor 140 may determine the surface temperature of the electronic device 100 according to the reference temperature sensed by the temperature sensor 110_1 and the reference temperature sensed by the temperature sensor 110_2. For example, the processor 140 may determine the surface temperature of the electronic device 100 according to the following equation (1).

ST=w1*RT1+w2*RT2 Equation (1)

wherein ST represents the surface temperature of the electronic device 100; RT1 represents the reference temperature sensed by the temperature sensor 110_1; RT2 represents the reference temperature sensed by the temperature sensor 110_3; w1 represents the weighting coefficient corresponding to the temperature sensor 110_1; w2 represents the weighting coefficient corresponding to the temperature sensor 110_2.

In another scenario, when the camera module 150 is in operation and the charging module 160 is not charging, the processor 140 may determine the surface temperature of the electronic device 100 according to the reference temperature sensed by the temperature sensor 110_1 and the reference temperature sensed by the temperature sensor 110_3. For example, the processor 140 may determine the surface temperature of the electronic device 100 according to the following equation (2).

ST=w3*RT1+w4*RT3 Equation (2)

wherein ST represents the surface temperature of the electronic device 100; RT1 represents the reference temperature sensed by the temperature sensor 110_1; RT3 represents the reference temperature sensed by the temperature sensor 110_3; w3 represents the weighting coefficient corresponding to the temperature sensor 110_1; w4 represents the weighting coefficient corresponding to the temperature sensor 110_3.

It should be noted that, in some embodiments, the weighting coefficient w3 may be the same as the weighting coefficient w1, and the weighting coefficient w2 may be the same as the weighting coefficient w4. In some other embodiments, the weighting coefficient w3 may be different from the weighting coefficient w1, and the weighting coefficient w2 may be different from the weighting coefficient w4. That is, the weighting coefficients may be different according to changes in the combination of the selected temperature sensors.

In another scenario, when the camera module 150 is not in operation and the charging module 160 is not charging, the processor 140 may determine the surface temperature of the electronic device 100 according to the reference temperatures sensed by the temperature sensors 110_1 to 110_3. For example, the processor 140 may determine the surface temperature of the electronic device 100 according to the following equation (3).

ST=w5*RT1+w6*RT2+w7*RT3 Equation (1)

wherein ST represents the surface temperature of the electronic device 100; RT1 represents the reference temperature sensed by the temperature sensor 110_1; RT3 represents the reference temperature sensed by the temperature sensor 110_3; w5 represents the weighting coefficient corresponding to the temperature sensor 110_1; w6 represents the weighting coefficient corresponding to the temperature sensor 110_2; w4 represents the weighting coefficient corresponding to the temperature sensor 110_3.

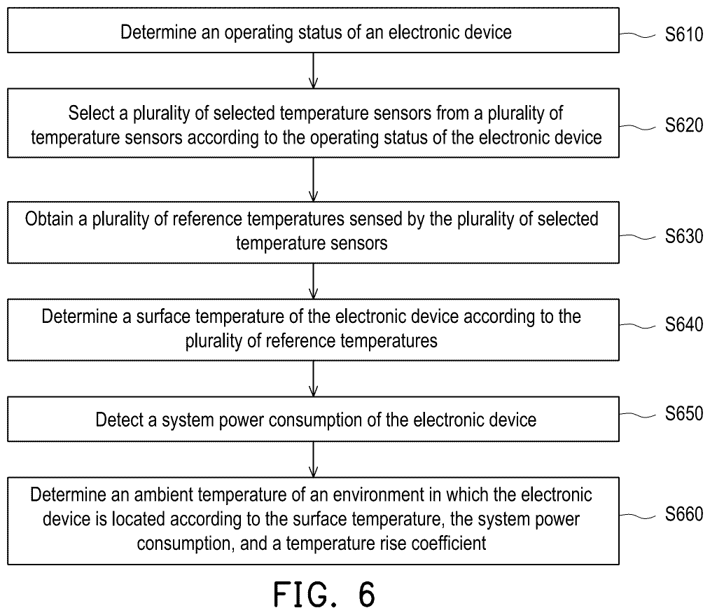

FIG. 6 is a flowchart of a method for detecting temperature shown according to an embodiment of the invention. Please refer to FIG. 1 and FIG. 6. The method of the present embodiment is applicable to the electronic device 100 in an above embodiment. The following describes the detailed steps of the method for detecting temperature of the present embodiment in conjunction with various elements in the electronic device 100.

In step S610, the processor 140 determines the operating status of the electronic device 100. In step S620, the processor 140 selects a plurality of selected temperature sensors from the plurality of temperature sensors 110_1 to 110_N according to the operating status of the electronic device 100. In step S630, the processor 140 obtains a plurality of reference temperatures sensed by the plurality of selected temperature sensors. In step S640, the processor 140 determines the surface temperature of the electronic device 100 according to the plurality of reference temperatures. The implementation contents of step S610 to step S640 may be as provided in the description of an above embodiment and are not repeated herein.

In step S650, the processor 140 detects a system power consumption of the electronic device 100. In step S660, the processor 140 determines the ambient temperature of the environment in which the electronic device 100 is located according to the surface temperature, the system power consumption, and the temperature rise coefficient. For example, the processor 140 may determine the ambient temperature of the environment in which the electronic device 100 is located according to the following equation (4). The temperature rise coefficient may be determined via experiments and tests, and the disclosure is not limited thereto.

Ambient temperature=surface temperature−(temperature rise coefficient*system power consumption) equation (4)

Specifically, the processor 140 may obtain the system power consumption (unit: watt) of the electronic device 100 by estimating via software, requesting from the power management chip, or monitoring the discharge status of the battery. Next, the processor 140 may calculate the ambient temperature of the environment in which the electronic device 100 is located according to the system power consumption and the surface temperature. Furthermore, when the surface temperature is very high but the system power consumption is not high, the processor 140 may infer that the electronic device 100 is in a high-temperature environment. Therefore, the processor 140 may notify the user via the human-machine interface device 120 to move the electronic device 100 to a low-temperature environment to prevent the temperature of the electronic device 100 from continuing to rise and causing harm.

Based on the above, in an embodiment of the invention, some selected temperature sensors may be selected from the plurality of temperature sensors disposed at different locations according to the operating status of the electronic device. Furthermore, the surface temperature of the electronic device may be accurately estimated according to the reference temperatures sensed by the selected temperature sensors. Therefore, since the estimation of the surface temperature may be more accurate, the temperature protection mechanism may be implemented and the user may be prompted in a timely manner. In this way, the performance stability and the service life of the electronic device may be further ensured, and the safety of the user may be improved at the same time.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A method for detecting temperature, adapted to an electronic device comprising a plurality of temperature sensors, comprising:
determining an operating status of the electronic device;
selecting a plurality of selected temperature sensors from the plurality of temperature sensors according to the operating status of the electronic device;
obtaining a plurality of reference temperatures sensed by the plurality of selected temperature sensors; and
determining a surface temperature of the electronic device according to the plurality of reference temperatures.

2. The method for detecting temperature of claim 1, wherein the plurality of temperature sensors comprise a plurality of thermal sensitive elements disposed on at least one circuit board.

3. The method for detecting temperature of claim 1, wherein the plurality of temperature sensors comprise a primary temperature sensor and at least one secondary temperature sensor, the primary temperature sensor is disposed in a hot area in the electronic device, and the at least one secondary temperature sensor is disposed in at least one cold area in the electronic device.

4. The method for detecting temperature of claim 3, wherein the selected temperature sensors comprise at least one of the primary temperature sensor and the at least one secondary temperature sensor.

5. The method for detecting temperature of claim 3, wherein the step of determining the operating status of the electronic device comprises:
determining whether a heat source element located near the at least one secondary temperature sensor is in operation.

6. The method for detecting temperature of claim 5, wherein the step of selecting the plurality of selected temperature sensors from the plurality of temperature sensors according to the operating status of the electronic device comprises:
selecting the at least one secondary temperature sensor as one of the plurality of selected temperature sensors when the heat source element located near the at least one secondary temperature sensor is not in operation; and
discarding the at least one secondary temperature sensor as one of the plurality of selected temperature sensors when the heat source element located near the at least one secondary temperature sensor is in operation.

7. The method for detecting temperature of claim 1, wherein the step of determining the surface temperature of the electronic device according to the plurality of reference temperatures comprises:
calculating a weighted sum of the plurality of reference temperatures respectively corresponding to the plurality of selected temperature sensors to determine the surface temperature of the electronic device.

8. The method for detecting temperature of claim 7, wherein the step of determining the surface temperature of the electronic device according to the plurality of reference temperatures further comprises:
determining a weighting coefficient corresponding to each of the plurality of reference temperatures according to the operating status of the electronic device.

9. The method for detecting temperature of claim 1, the method further comprising:
detecting a system power consumption of the electronic device; and
determining an ambient temperature of an environment in which the electronic device is located according to the surface temperature, the system power consumption, and a temperature rise coefficient.

10. An electronic device, comprising:
a plurality of temperature sensors;
a processor coupled to the plurality of temperature sensors and configured to:
determine an operating status of the electronic device;
select a plurality of selected temperature sensors from the plurality of temperature sensors according to the operating status of the electronic device;
obtain a plurality of reference temperatures sensed by the plurality of selected temperature sensors; and
determine a surface temperature of the electronic device according to the plurality of reference temperatures.
